(19) United States
(12) Patent Application Publication
(10) Pub. No.: US 2014/0133097 A1
(43) Pub. Date: May 15, 2014

(54) COOLING SYSTEM, METHOD FOR DETECTING CLOGGING OF AIR FILTER AND SIGNAL TRANSMISSION APPARATUS

(71) Applicant: FUJITSU LIMITED, Kawasaki-shi (JP)

(72) Inventors: Kouichi Kuramitsu, Setagaya (JP); Kazuhiro IINO, Yokohama (JP); Jyunichi ISHIWATARI, Kawasaki (JP); Hideki Kobayashi, Yokohama (JP)

(73) Assignee: FUJITSU LIMITED, Kawasaki-shi (JP)

(21) Appl. No.: 14/068,320

(22) Filed: Oct. 31, 2013

(30) Foreign Application Priority Data
Nov. 15, 2012 (JP) 2012-251353

(51) Int. Cl. F04D 27/00; H05K 7/20; G01N 15/08

(52) U.S. Cl. CPC F04D 27/001; G01N 15/082; H05K 7/20181; H05K 7/20209
USPC 361/695; 415/47; 415/17; 73/38

(57) ABSTRACT

A cooling system includes: a cooling fan configured to take in air through an air filter and to send the air to one or more electronic components; one or more first temperature detectors configured to detect temperatures of the one or more electronic components; a revolution controller configured to control a number of revolutions of the cooling fan on basis of the temperatures detected by the one or more first temperature detectors; and a clogging detector configured to, when the number of revolutions of the cooling fan controlled by the revolution controller is greater than a reference number of revolutions of the cooling fan that makes the temperature of the one or more electronic components less than upper-limit temperatures of the one or more electronic components, detect a clogging condition for the air filter.

### CROSS-REFERENCE TO RELATED APPLICATION

This application is based upon and claims the benefit of priority from the prior Japanese Patent Application No. 2012-251353 filed on Nov. 15, 2012, the entire contents of which are incorporated herein by reference.

### FIELD

The embodiment discussed herein is related to a cooling system and a method for detecting clogging of an air filter.

### BACKGROUND

A transmission apparatus for transmitting signals, for example, has many electronic components mounted thereon, and the calorific value of the electronic components increases as the apparatus size increases. To cool the electronic components, the transmission apparatus includes a cooling system including a cooling fan.

The number of revolutions of the cooling fan is controlled, for example, based on an ambient temperature detected by a temperature sensor or the like. The percentage of power consumed for cooling of power consumed by the entire apparatus is, for example, 20%. For this reason, reductions in the power consumption of the cooling system contribute to reductions in the power consumption of the entire apparatus.

To reduce entry of dust or the like into the apparatus resulting from air blast, the cooling fan is provided with an air filter at an air inlet thereof. When the air filter becomes clogged, the capacity of the cooling system would be reduced. For this reason, the air filter is replaced periodically (for example, every six months).

For example, a 1000 to 2000-meter-altitude highland may be selected as the installation environment of a transmission apparatus. While the atmospheric pressure of a zero-meter-altitude lowland is about 1013 hPa, the atmospheric pressure of a 1000-meter-altitude highland is about 904 hPa. That is, the air density of the highland is lower than that of the lowland.

Accordingly, when the cooling fan is operated in the highland environment using the lowland environment as a reference, the cooling capacity of the cooling system would be insufficient. If the air filter becomes clogged, the cooling capacity would be further insufficient. This may disadvantageously raise the intra-apparatus temperature faster than in the lowland environment, causing the electronic component to fail. Conversely, when the cooling fan is operated in the lowland environment using the highland environment as a reference, the cooling capacity of the cooling system would be excessive, thereby consuming more power than what the cooling system has to obtain.

An example of measures against this problem is to shorten the replacement cycle of the air filter. In this case, however, the air filter that is still available may be replaced. This is uneconomical in terms of management of the apparatus. The above problem applies to transmission apparatuses, as well as to other types of apparatuses.

The following is reference documents:

### [Document 1] Japanese Laid-open Patent Publication No. 2011-199205,

### [Document 2] Japanese Laid-open Patent Publication No. 2004-263989,

### [Document 3] Japanese Laid-open Patent Publication No. 2000-194072.

### SUMMARY

According to an aspect of the invention, a cooling system includes: a cooling fan configured to take in air through an air filter and to send the air to one or more electronic components; one or more first temperature detectors configured to detect temperatures of the one or more electronic components; a revolution controller configured to control a number of revolutions of the cooling fan on basis of the temperatures detected by the one or more first temperature detectors; and a clogging detector configured to, when the number of revolutions of the cooling fan controlled by the revolution controller is greater than a reference number of revolutions of the cooling fan that makes the temperature of the one or more electronic components less than upper-limit temperatures of the one or more electronic components, detect a clogging condition for the air filter.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a front view illustrating an example of a transmission apparatus;

FIG. 2 is a configuration diagram illustrating functions and configuration of a cooling system according to an embodiment;

FIG. 3 is a graph illustrating the duty ratio of a pulse width modulation (PWM) signal versus the number of revolutions of a cooling fan;

FIG. 4 is a table illustrating temperature parameters of electronic components;

FIG. 5 is a table indicating operations corresponding to component temperature conditions;

FIG. 6 is a graph illustrating the ambient temperature versus the reference number of revolutions when the atmospheric pressure is fixed;

FIG. 7 is a graph illustrating an example of the ambient temperature versus changes in the component temperature when the number of revolutions is fixed;

FIG. 8 is a graph illustrating an example of the ambient temperature versus changes in the number of revolutions;

FIG. 9 is a graph illustrating an example of changes in atmospheric pressure versus changes in the reference number of revolutions;

FIG. 10 is a table illustrating an example of a table of the reference number of revolutions;

FIG. 11 is a graph illustrating another example of changes in atmospheric pressure versus changes in the reference number of revolutions;

FIG. 12 is a flowchart illustrating a process of controlling the number of revolutions; and

FIG. 13 is a flowchart illustrating a process of detecting clogging of an air filter.

### DESCRIPTION OF EMBODIMENT

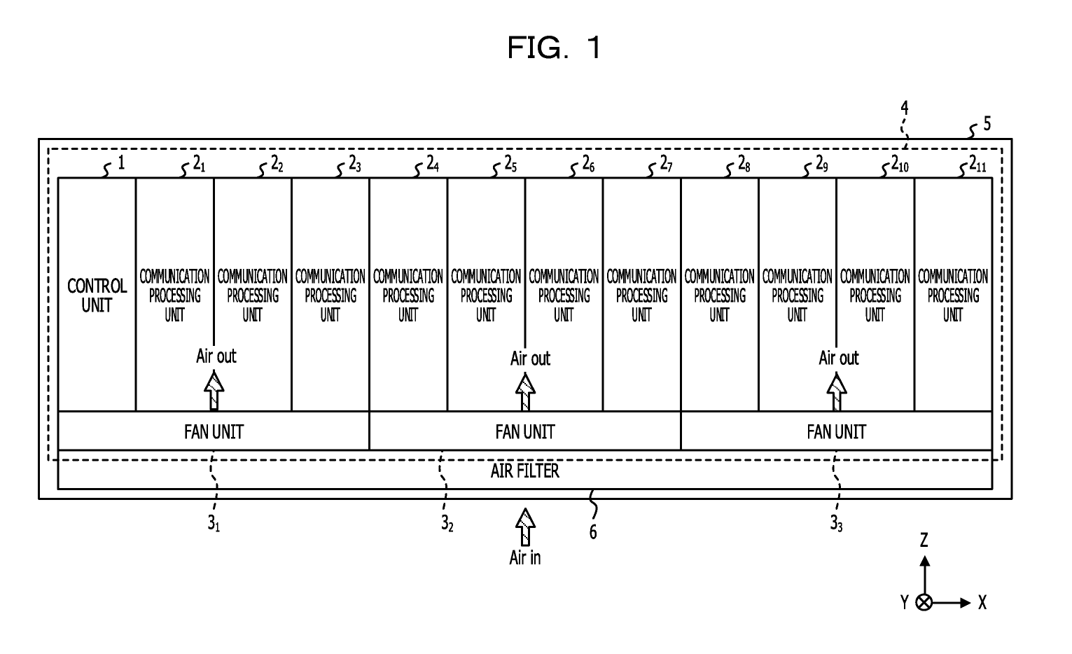

FIG. 1 is a front view illustrating an example of a transmission apparatus. The transmission apparatus includes a control unit 1, multiple communication processing units 2₁ to 2₁₁, multiple fan units 3₁ to 3₃, a line connecting substrate 4, a cabinet 5, and an air filter 6. While the transmission apparatus is used as an example application of a cooling system according to the present embodiment, the cooling system may be applied to any other types of apparatuses that have to be cooled.

The control unit 1 and the communication processing units 2₁ to 2₁₁ each include a printed circuit board expanding in a y-z plane in FIG. 1 and are housed in multiple slots formed along a z direction in the cabinet 5 having a rectangular parallelepiped shape. The communication processing units 2₁ to 2₁₁ perform processes of transmitting signals through multiple communication lines.

The control unit 1 controls the communication processing units 2₁ to 2₁₁ and the fan units 3₁ to 3₃. It also performs an alarm detection process, or the like. The control unit 1 and the communication processing units 2₁ to 2₁₁ have, on the printed circuit boards thereof, one or more electronic components for performing functions.

The line connecting substrate 4 expands in an x-z plane in FIG. 1 and is disposed on the bottom of the transmission apparatus. The line connecting substrate 4 is connected to the control unit 1, the communication processing units 2₁ to 2₁₁, and the fan units 3₁ to 3₃ through a connecting device, such as an electrical connector. Thus, the units 1, 2₁ to 2₁₁, and 3₁ to 3₃ are electrically connected together, enabling power supply and intra-apparatus communication.

The fan units 3₁ to 3₃ are housed in slots below the control unit 1 and the communication processing units 2₁ to 2₁₁. The fan units 3₁ to 3₃ sends air to the control unit 1 and the communication processing units 2₁ to 2₁₁ under the control of the control unit 1. Thus, the electric components included in the control unit 1 and the communication processing units 2₁ to 2₁₁ are cooled.

The fan units 3₁ to 3₃ take in air through the air filter 6 disposed there below, as shown by reference sign Ain, and send the air toward the upper part of the transmission apparatus, as shown by reference sign Aout. That is, cooling air enters the apparatus through the air filter 6 and travels toward the upper part of the transmission apparatus along the plate surfaces of the control unit 1 and the communication processing units 2₁ to 2₁₁ (in the z direction of FIG. 1). The lower part (baseplate) and the upper part (top plate) of the transmission apparatus have an air inlet and an air outlet (not illustrated), respectively.

The air filter 6 is disposed at the air inlet in such a manner so as to expand in an x-y plane of FIG. 1 and reduces entry of dust or the like into the apparatus when the fan units 3₁ to 3₃ take in air. While the air filter 6 is, for example, a polyurethane foam, it may be other types of dust filters.

The air filter 6 becomes clogged when it takes in an amount of dust exceeding an allowance. The clogging of the air filter 6 hampers sufficient intake of air by the fan units 3₁ to 3₃, reducing the cooling capacity of the fan units 3₁ to 3₃. For this reason, the control unit 1 detects the clogging of the air filter 6 and outputs a clogging alarm to urge the user to replace the air filter 6.

The control unit 1, the communication processing units 2₁ to 2₁₁, and the fan units 3₁ to 3₃ are detachable from the cabinet 5. For this reason, the targets that the fan units 3₁ to 3₃ mainly cool vary according to the housing state of the cabinet 5. For example, in FIG. 1, the fan unit 3₁ typically mainly cools the control unit 1 and the communication processing units 2₁ to 2₃; however, when the communication processing unit 2₁ is not housed, the fan unit 3₁ mainly cools the control unit 1 and the communication processing units 2₂ and 2₃. Since there is no difference in processing among the fan units 3₁ to 3₃, the cooling system of the fan unit 3₁ will be described below as a representative.

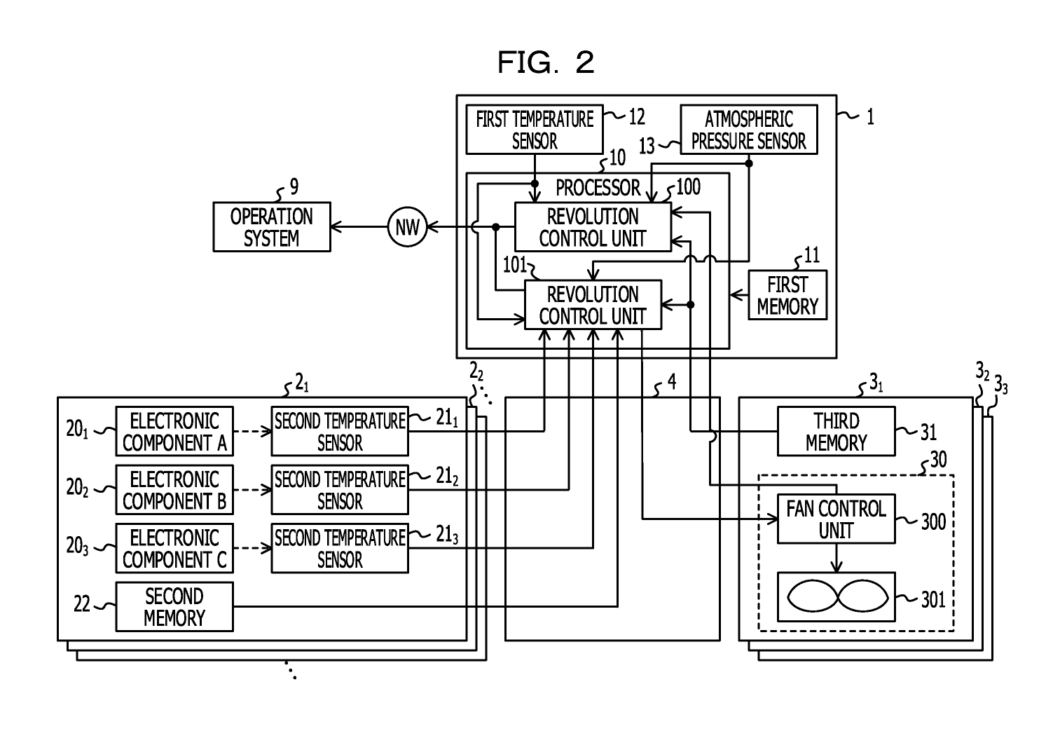

FIG. 2 is a block diagram illustrating functions and configuration of the cooling system according to the present embodiment. As described above, the control unit 1, the communication processing units 2₁ to 2₁₁, and the fan units 3₁ to 3₃ communicate with one another through the line connecting substrate 4. The communication device is, for example, an Inter-Integrated Circuit (I2C), but not limited thereto and may be a local area network (LAN).

The control unit 1 includes a processor 10, a first memory 11, a first temperature sensor (second temperature detector) 12, and an atmospheric pressure sensor (atmospheric pressure detection unit) 13. The processor 10 is, for example, a central processing unit (CPU) and runs according to a predetermined program (software). The first memory 11 is storing the program that runs the processor 10, or the like. When the processor 10 reads the program from the first memory 11, a clogging detection unit 100 and a revolution control unit 101 are generated as cooling system-related functions.

The clogging detection unit 100 detects clogging of the air filter 6 and notifies an operation system 9 of the occurring clogging through a network NW. The operation system 9 is, for example, a network management apparatus for managing the transmission apparatus. The revolution control unit 101 controls the number of revolutions of the cooling fan of each of the fan units 3₁ to 3₃.

The first temperature sensor 12 detects the temperature outside the transmission apparatus (hereafter referred to as the ambient temperature) and notifies the clogging detection unit 100 and the revolution control unit 101 of the detected ambient temperature. The first temperature sensor 12 is disposed, for example, adjacent to an inlet for the cooling air from the fan units 3₁ to 3₃. Instead of in the control unit 1, the first temperature sensor 12 may be disposed in the communication processing units 2₁ to 2₁₁, line connecting substrate 4, or fan units 3₁ to 3₃.

The atmospheric pressure sensor 13 detects atmospheric pressure and notifies the clogging detection unit 100 and the revolution control unit 101 of the detected atmospheric pressure. The detected atmospheric pressure is used with the ambient temperature to detect clogging of the air filter 6 and to determine the initial value of the number of revolutions, as will be described later. Instead of in the control unit 1, the atmospheric pressure sensor 13 may be disposed in the communication processing units 2₁ to 2₁₁, line connecting substrate 4, or fan units 3₁ to 3₃.

The communication processing units 2₁ to 2₁₁ each include multiple electronic components A, B, and C 20₁ to 20₃, multiple second temperature sensors (first temperature detector) 21₁ to 21₃, and a second memory 22. The electronic components A, B, and C 20₁ to 20₃ are communication processing devices or the like and perform the functions of the communication processing unit including these components.

The second temperature sensors 21₁ to 21₃ detect the temperatures of the electronic components A, B, and C 20₁ to 20₃ (hereafter referred to as the component temperatures), respectively, and notifies the revolution control unit 101 of the detected component temperatures. The second temperature sensors 21₁ to 21₃ are disposed, for example, on the leeward side of the mounting positions of the electronic components A, B, and C 20₁ to 20₃ with respect to the cooling air from the fan units 3₁ to 3₃. The second temperature sensors 21₁ to 21₃ do not necessarily have to be disposed separately from the electronic components A, B, and C 20₁ to 20₃ as described above and may be included therein. While the second temperature sensors 21₁ to 21₃ are disposed so as to correspond to all the electronic components A, B, and C 20₁ to 20₃ in the communication processing units 2₁ to 2₁₁, a second temperature sensor may be disposed so as to correspond to only an electronic component having a relatively high calorific value.

The second memory (second storage unit) 22 is storing temperature parameters of the electronic components A, B, and C 20₁ to 20₃, as will be described later. The revolution control unit 101 controls the number of revolutions of each of the fan units 3₁ to 3₃ based on the temperature parameters read from the second memory and the component temperatures detected by the second temperature sensors 21₁ to 21₃.

The fan units 3₁ to 3₃ each include a cooling fan 30 and a third memory (first storage unit) 31. The cooling fan 30 includes a fan control unit 300 and a fan motor 301. The fan control unit 300 controls the fan motor 301 based on the number of revolutions notified of by the revolution control unit 101.

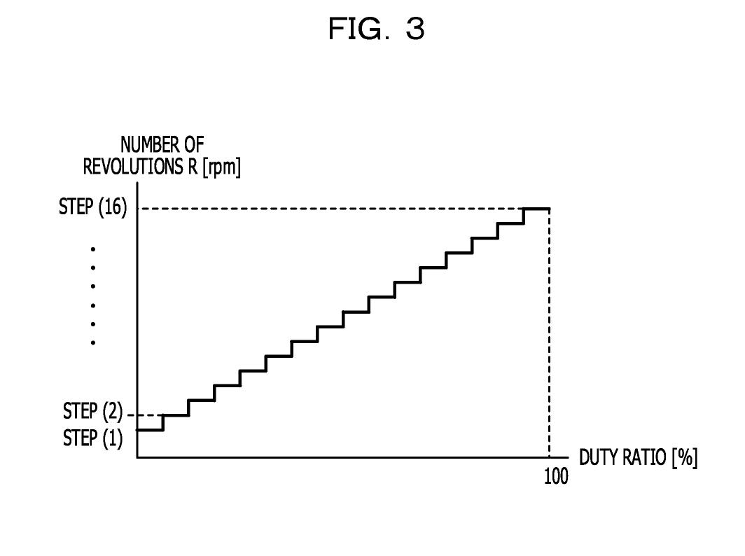

The fan control unit 300 rotates the fan motor 301 with a desired number of revolutions, for example, by outputting a PWM signal to the fan motor 301 and adjusting the duty ratio of the PWM signal. FIG. 3 is a graph illustrating the duty ratio of the PWM signal versus the number of revolutions of the cooling fan 30.

In this example, the number of revolutions R of the fan motor 301 is composed of steps (1) to (16) obtained by dividing a range of 0 to the maximum number of revolutions by 16. The revolution control unit 101 controls the number of revolutions R on a step basis. The total number of steps does not necessarily have to be 16. Further, instead of in such steps, the number of revolutions R may be controlled, for example, linearly based on the voltage value of a control signal.

Now, a process of controlling the number of revolutions R will be described. The revolution control unit 101 controls the number of revolutions R of the cooling fan 30 on the basis of the component temperatures tc detected by the one or more second temperature sensors 21₁ to 21₃. To control the number of revolutions R, the revolution control unit 101 reads the temperature parameters of the electronic components A, B, and C 20₁ to 20₃ from the second memory 22.

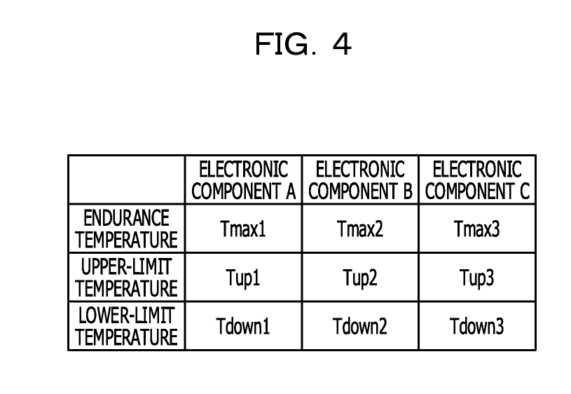

FIG. 4 is a table indicating the temperature parameters of the electronic components A, B, and C 20₁ to 20₃. The temperature parameters include endurance temperatures Tmax1 to Tmax3, upper-limit temperatures Tup1 to Tup3, and lower-limit temperatures Tdown1 to Tdown3 corresponding to the electronic components A, B, and C 20₁ to 20₃, respectively. Among these, the endurance temperatures Tmax1 to Tmax3 are the highest; the lower-limit temperatures Tdown1 to Tdown3 are the lowest.

The endurance temperatures Tmax1 to Tmax3 are the absolute maximum temperature ratings of the electronic components A, B, and C 20₁ to 20₃. That is, if any of the component temperatures of the electronic components A, B, and C 20₁ to 20₃ exceeds the corresponding endurance temperature, the electronic component may fail.

The upper-limit temperatures Tup1 to Tup3 and the lower-limit temperatures Tdown1 to Tdown3 define temperature ranges in which the performance of the electronic components A, B, and C 20₁ to 20₃ is guaranteed. The temperature widths between the upper-limit temperatures Tup1 to Tup3 and the lower-limit temperatures Tdown1 to Tdown3 are, for example, appropriately 10° C. and may be the same or different among the electronic components A, B, and C 20₁ to 20₃. The revolution control unit 101 controls the number of revolutions R so that the component temperatures of all the electronic components A, B, and C 20₁ to 20₃ do not exceed the upper-limit temperatures Tup1 to Tup3, respectively.

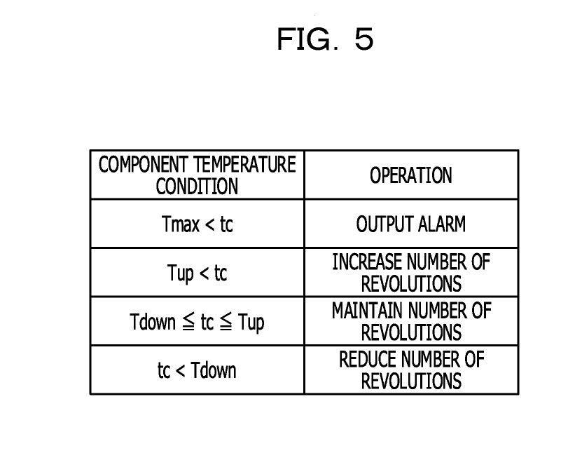

FIG. 5 is a table indicating operations corresponding to component temperature conditions. Based on the temperature parameters read from the second memory 22 and the component temperatures tc notified of by the second temperature sensors 21₁ to 21₃, the revolution control unit 101 determines which of the component temperature conditions illustrated in FIG. 5 applies to each of the electronic components A, B, and C 20₁ to 20₃. In FIG. 5, Tmax, Tup, and Tdown typify the endurance temperatures Tmax1 to Tmax3, the upper-limit temperatures Tup1 to Tup3, and the lower-limit temperatures Tdown1 to Tdown3, respectively. In the following description, it is assumed that the fan units 3₁ to 3₃ cool only the communication processing unit 2₁.

When the component temperature tc of at least one of the electronic components A, B, and C 20₁ to 20₃ is higher than the endurance temperature Tmax of the electronic component (Tmax<tc), the revolution control unit 101 detects a unit failure. At this time, the revolution control unit 101 outputs an alarm indicating the unit failure to the operation system 9 through the network NW. In this case, an additional condition has to be met that the number of revolutions R is the maximum number of revolutions, that is, the number of revolutions corresponding to step (16) in the example of FIG. 3.

When the component temperature tc of at least one of the electronic components A, B, and C 20₁ to 20₃ is higher than the upper-limit temperature (first threshold) Tup corresponding to the electronic component (Tup<tc), the revolution control unit 101 increases the number of revolutions R. That is, the revolution control unit 101 controls the number of revolutions R so that the component temperatures tc of all the electronic components A, B, and C 20₁ to 20₃ are equal to or lower than the upper-limit temperatures Tup1 to Tup3, respectively. The extent to which the number of revolutions is increased does not necessarily have to be a single step in FIG. 3 and may be, for example, multiple steps in accordance with the temperature width between the upper-limit temperature Tup and the lower-limit temperature Tdown.

When the component temperature tc of at least one of the electronic components A, B, and C 20₁ to 20₃ falls between the upper-limit temperature Tup and the lower-limit temperature Tdown of the electronic component (Tdown≦tc≦Tup), the revolution control unit 101 maintains the number of revolutions R. In this case, however, an additional condition has to be met that “Tup<tc” does not apply to any of the electronic components A, B, and C 20₁ to 20₃.

When the component temperatures of all the electronic components A, B, and C 20₁ to 20₃ are lower than the lower-limit temperatures Tdown (second thresholds) corresponding to the electronic components (tc<Tdown), the revolution control unit 101 reduces the number of revolutions R. That is, if the component temperatures tc of all the electronic components A, B, and C 20₁ to 20₃ are sufficiently lower than the upper-limit temperatures Tup, respectively, the power consumption of the fan units 3₁ to 3₃ is reduced.

As seen above, the revolution control unit 101 controls the number of revolutions R in the following order of priority: increase of the number of revolutions R, maintenance thereof, and reduction thereof. Accordingly, the component temperatures tc of the electronic components A, B, and C 20₁ to 20₃ having the smallest margin to the upper-limit temperature Tup fall within between the upper-limit temperature Tup and the lower-limit temperature Tdown. Thus, the component temperatures tc of all the electronic components A, B, and C 20₁ to 20₃ fall within the temperature range in which the performance of the electronic components is guaranteed, and the number of revolutions R of the cooling fan 30 is reduced. Instead of on the basis of the component temperatures tc of all the electronic components A, B, and C 20₁ to 20₃, the revolution control unit 101 may control the number of revolutions R on the basis of the component temperature tc of any one electronic component.

If the fan units 3₁ to 3₃ cool the multiple communication processing units 2₁ to 2₁₁, the revolution control unit 101 determines which of the component temperature conditions applies to each electronic component, with respect to each of the communication processing units 2₁ to 2₁₁. Of operations (see FIG. 5) corresponding to the determinations with respect to the communication processing units 2₁ to 2₁₁, the revolution control unit 101 performs increase of the number of revolutions R with the highest priority, maintenance thereof with the second highest priority, and reduction thereof with the lowest priority.

For example, assume that the fan unit 3₃ cools the communication processing units 2₈ to 2₁₁. If an operation corresponding to the determination with respect to at least one of the communication processing units 2₈ to 2₁₁ is increase of the number of revolutions R, the revolution control unit 101 increases the number of revolutions R. If operations corresponding to the determinations with respect to the communication processing units 2₈ and 2₁₀ are maintenance of the number of revolutions R and if operations corresponding to the determinations with respect to the other communication processing units, 2₉ and 2₁₁, are reduction of the number of revolutions R, the revolution control unit 101 maintains the number of revolutions R. If operations corresponding to the determinations with respect to all the communication processing units 2₈ to 2₁₁ are reduction of the number of revolutions R, the revolution control unit 101 reduces the number of revolutions R.

The revolution control unit 101 may perform the above determination process with respect to all the communication processing units 2₁ to 2₁₁ housed in the transmission apparatus and commonly control the numbers of revolutions R of the fan units 3₁ to 3₃. The revolution control unit 101 may also perform, on the control unit 1, a determination process similar to those on the communication processing units 2₁ to 2₁₁. In this case, as with the communication processing units 2₁ to 2₁₁, the control unit 1 is provided with temperature sensors for detecting the component temperatures of electronic components mounted thereon and a memory for storing temperature parameters corresponding to the electronic components.

The detachable, common communication processing units 2₁ to 2₁₁ each include the electronic components A, B, and C 20₁ to 20₃ and the second memory 22. The temperature parameters stored in the second memory 22 are values specific to the electronic components A, B, and C 20₁ to 20₃ included in the same communication processing unit.

Accordingly, even when any of the communication processing units 2₁ to 2₁₁ is replaced for reasons such as a failure, temperature parameters corresponding to the electronic components A, B, and C 20₁ to 20₃ of a new communication processing unit are used. Thus, even when any of the communication processing units 2₁ to 2₁₁ is replaced, the revolution control unit 101 may control the number of revolutions R without problems.

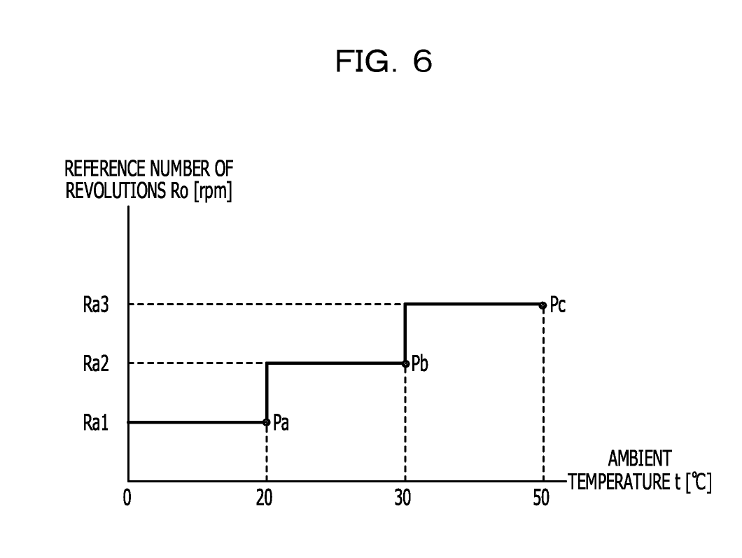

Next, a process of detecting clogging of the air filter 6 will be described. The third memory 31 is storing a table indicating the correspondence between the atmospheric pressure and the reference number of revolutions for each of the ranges of the ambient temperature t. FIG. 6 is a graph illustrating the ambient temperature t (° C.) versus the reference number of revolutions Ro (rpm) when the atmospheric pressure is fixed.

The reference number of revolutions Ro is the number of revolutions which is assumed to be sufficient to make the component temperatures tc of the electronic components A, B, and C 20₁ to 20₃ equal to or lower than the upper-limit temperatures Tup1 to Tup3, respectively, in the heat dissipation design (wind power generated by the cooling fan 30, or the like) of the cooling system. The reference number of revolutions Ro is defined for each of the ranges (0 to 20° C., 20 to 30° C., and 30 to 50° C.) of the ambient temperature t. Note that the ranges depicted in FIG. 6 are illustrative only.

The component temperatures tc of the electronic components A, B, and C 20₁ to 20₃ are assumed to be equal to or lower than the upper-limit temperatures Tup1 to Tup3, respectively, even when the number of revolutions R of the cooling fan 30 is smaller than the reference number of revolutions Ro. For example, when the ambient temperature t is 20° C. and when the number of revolutions R of the cooling fan 30 is Ra1, the component temperature tc is assumed to be equal to or lower than the upper-limit temperature Tup (see reference sign Pa). Similarly, when the ambient temperature t is 30° C. or 50° C. and when the number of revolutions R of the cooling fan 30 is Ra2 or Ra3, the component temperature tc is assumed to be equal to or lower than the upper-limit temperature Tup (see reference sign Pb or Pc).

To allow the cooling capacity leeway, the reference number of revolutions Ro is determined assuming that the air filter 6 has absorbed a predetermined amount of dust or the like (for example, assuming that the transmission apparatus has been driven for six months with dust suspended at a particular density). The reference number of revolutions Ro is also determined considering noise emitted by the fan motor 301.

The revolution control unit 101 selects the reference number of revolutions Ro in accordance with the ambient temperature t detected by the first temperature sensor 12 and uses the selected reference number of revolutions Ro as the initial value of the number of revolutions R. Assume that the reference numbers of revolutions Ra1, Ra2, and Ra3 in FIG. 6 correspond to steps (5), (7), and (9), respectively, in FIG. 3. When the ambient temperature t is 0 to 20° C. after the transmission apparatus is started, the revolution control unit 101 controls the number of revolutions R so that the number of revolutions R becomes the number of revolutions corresponding to step (5). When the ambient temperature t is 20 to 30° C., the revolution control unit 101 controls the number of revolutions R so that the number of revolutions R becomes the number of revolutions corresponding to step (7). When the ambient temperature t is 30 to 50° C., it controls the number of revolutions R so that the number of revolutions R becomes the number of revolutions corresponding to step (9). As seen above, the initial value of the number of revolutions R serves as an optimum value corresponding to the ambient temperature t, and the amount of control that has to be performed to stabilize the number of revolutions R is reduced. As a result, power consumption is reduced.

On the other hand, the clogging detection unit 100 uses the reference number of revolutions Ro as a threshold for detecting clogging of the air filter 6. When the air filter 6 becomes clogged, the cooling capacity becomes insufficient even if the number of revolutions R of the cooling fan is the reference number of revolutions Ro. As a result, the component temperatures tc of the electronic components A, B, and C 20₁ to 20₃ exceed the upper-limit temperatures Tup1 to Tup3. At this time, the revolution control unit 101 increases the number of revolutions R to make the component temperatures tc lower than the upper-limit temperatures Tup1 to Tup3. Accordingly, the number of revolutions R becomes greater than the reference number of revolutions Ro.

When the number of revolutions R acquired from the fan control unit 300 by the clogging detection unit 100 is greater than the reference number of revolutions Ro, the clogging detection unit 100 determines that clogging has occurred in the air filter 6 and detects the clogging. That is, when the number of revolutions R controlled by the revolution control unit 101 exceeds the reference number of revolutions Ro, which is assumed to exert a sufficient cooling capacity when the degree of clogging of the air filter 6 is negligible, the clogging detection unit 100 determines that clogging has occurred in the air filter 6.

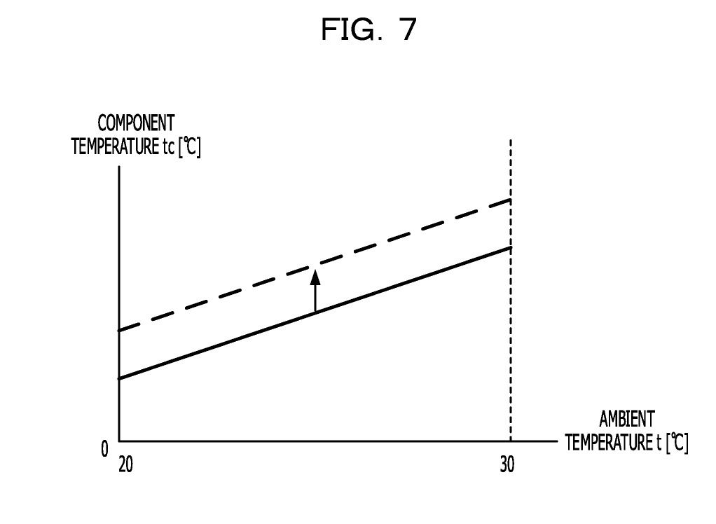

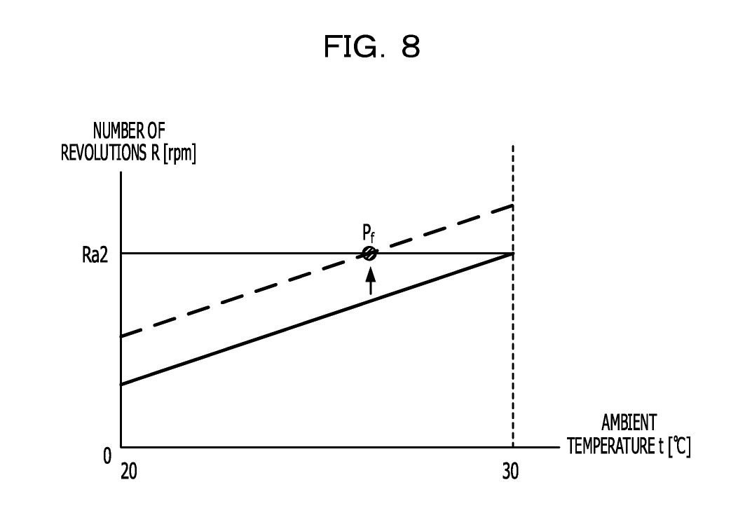

Next, referring to FIGS. 7 and 8, there will be described the effect of the installation environment of the transmission apparatus on the process of detecting clogging of the air filter 6. FIG. 7 is a graph illustrating an example of the ambient temperature t versus changes in the component temperature tc when the number of revolutions R is fixed. In FIG. 7, a solid line represents the component temperature tc when the transmission apparatus is installed on a lowland; a dotted line represents the component temperature tc when the transmission apparatus is installed on a highland. While FIG. 7 illustrates, as an example, changes in the component temperature tc when the ambient temperature t is in a range of 20 to 30° C., the same applies to other ranges.

The component temperature tc substantially rises in proportion to rises in the ambient temperature t. In the highland, air density is lower than that in the lowland, and the cooling capacity of the cooling fan 30 is reduced. Accordingly, if the number of revolutions R is the same, the component temperature tc in the highland becomes higher than the component temperature tc in the lowland (see an arrow).

FIG. 8 is a graph illustrating an example of the ambient temperature t versus changes in the number of revolutions R. In FIG. 8, a solid line represents the number of revolutions R when the transmission apparatus is installed on lowland; a dotted line represents the number of revolutions R when the transmission apparatus is installed on a highland.

As described above, the revolution control unit 101 controls the number of revolutions R so that the component temperatures tc of all the electronic components A, B, and C 20₁ to 20₃ fall within the respective temperature ranges in which the performance of the electronic components is guaranteed. Accordingly, the number of revolutions R is increased as the ambient temperature t rises. In the highland, the cooling capacity of the cooling fan 30 is reduced. Thus, the number of revolutions R becomes greater than that in the lowland (see an arrow), exceeding the reference number of revolutions Ra2 (see reference sign P_{f}). Accordingly, if the reference number of revolutions Ra2 is used as a threshold, the clogging detection unit 100 may erroneously detect clogging even when the air filter 6 is not clogged.

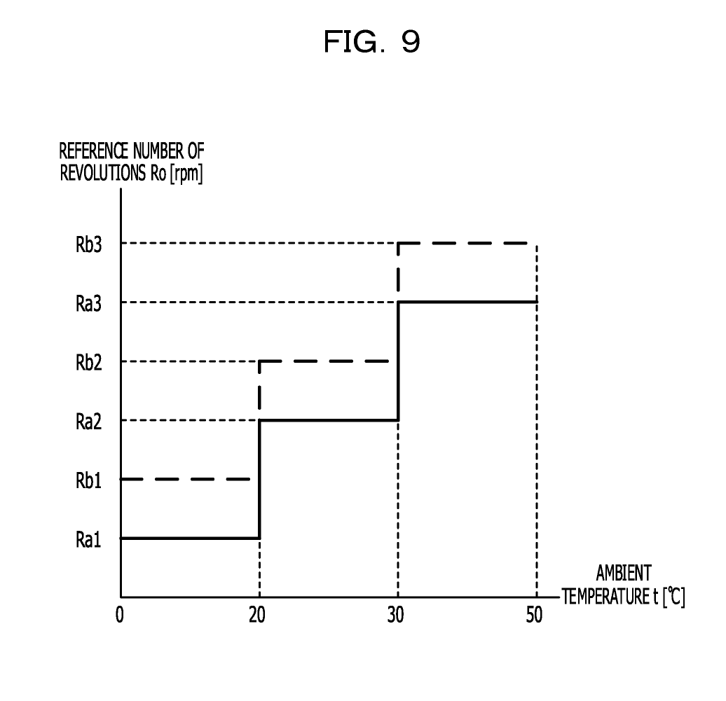

In view of the foregoing, the cooling system according to the present embodiment selects the reference number of revolutions Ro serving as a threshold in accordance with the atmospheric pressure p in order to detect a similar degree of clogging regardless of the installation environment of the transmission apparatus. FIG. 9 is a graph illustrating an example of changes in atmospheric pressure versus changes in the reference number of revolutions Ro. In FIG. 9, a solid line represents the reference number of revolutions Ro at the atmospheric pressure (904 to 1013 hPa) in a lowland (altitude of 0 to 1000 m); a dotted line represents the reference number of revolutions Ro at the atmospheric pressure (804 to 904 hPa) in a highland (altitude of 1000 to 2000 m).

For example, when the ambient temperature t is in a range of 0 to 20° C., the reference number of revolutions Ro is Ra1 in the lowland; it is Rb1 (>Ra1) in the highland. Similarly, when the ambient temperature t is in a range of 20 to 30° C. or in a range of 30 to 50° C., the reference numbers of revolutions Ro is Ra2 or Ra3 in the lowland; it is Rb2 (>Ra2) or Rb3(>Ra3) in the highland. The reference numbers of revolutions Rb1 to Rb3 corresponding to the respective ranges correspond to, for example, steps (6), (8), and (10), respectively, in FIG. 3.

Since the clogging detection unit 100 selects an optimum threshold corresponding to the atmospheric pressure p, it does not erroneously detect clogging of the air filter 6.

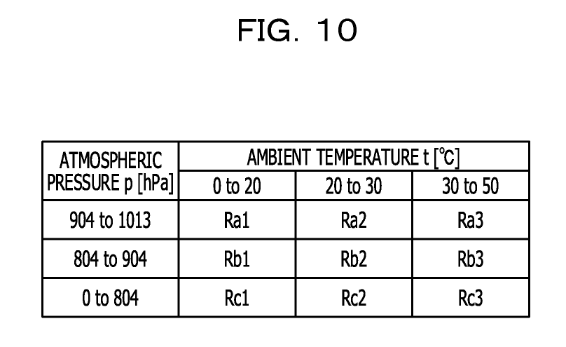

FIG. 10 is a table illustrating an example of a table of the reference numbers of revolutions Ro. In this example, the atmospheric pressure p is divided into a range of 0 to 804 hPa, a range of 804 to 904 hPa, and a range of 904 to 1013 hPa, and the reference numbers of revolutions Ro are defined for each range. The reference number of revolutions Ro is defined in accordance with characteristics specific to each fan motor 301. The range of the atmospheric pressure p of 0 to 804 hPa corresponds to a highland at an altitude of 2000 m or more.

This table is stored in the third memory 31 of each of the fan units 3₁ to 3₃, and the third memory 31 and the cooling fan 30 are disposed in each of the detachable, common fan units 3₁ to 3₃. Accordingly, even when any of the fan units 3₁ to 3₃ is replaced for reasons such as a failure, a table corresponding to characteristics specific to the fan motor 301 of a new fan unit is used. Thus, clogging of the air filter 6 is detected without problems.

The clogging detection unit 100 reads the table illustrated in FIG. 10 from the third memory 31 and refers to the table. The clogging detection unit 100 selects the reference number of revolutions Ro corresponding to the atmospheric pressure p detected by the atmospheric pressure sensor 13 and the ambient temperature t detected by the first temperature sensor. For example, when the atmospheric pressure is 700 hPa and the ambient temperature is 10° C., the clogging detection unit 100 selects Rc1 as the reference number of revolutions Ro, that is, as a threshold for a clogging detection process.

When the number of revolutions R controlled by the revolution control unit 101 is greater than the selected reference number of revolutions Ro, the clogging detection unit 100 detects that clogging has occurred in the air filter 6. As seen above, according to the cooling system according to the present embodiment, it is possible to accurately detect clogging of the air filter 6 regardless of the installation environment of the transmission apparatus. Further, the cooling system according to the present embodiment may cope with both installation environments, that is, a highland and a lowland. Thus, it is possible to use a heat dissipation structure common to both installation environments and thus to reduce apparatus cost.

Further, the revolution control unit 101 refers to the table of the reference numbers of revolutions Ro and uses the reference number of revolutions Ro corresponding to the atmospheric pressure p detected by the atmospheric pressure sensor 13 as the initial value of the number of revolutions R. Accordingly, the initial value of the number of revolutions R serves as an optimum value corresponding to the ambient temperature t, as well as corresponding to the atmospheric pressure p, and the amount of control that has to be performed to stabilize the number of revolutions R is reduced. As a result, power consumption is reduced.

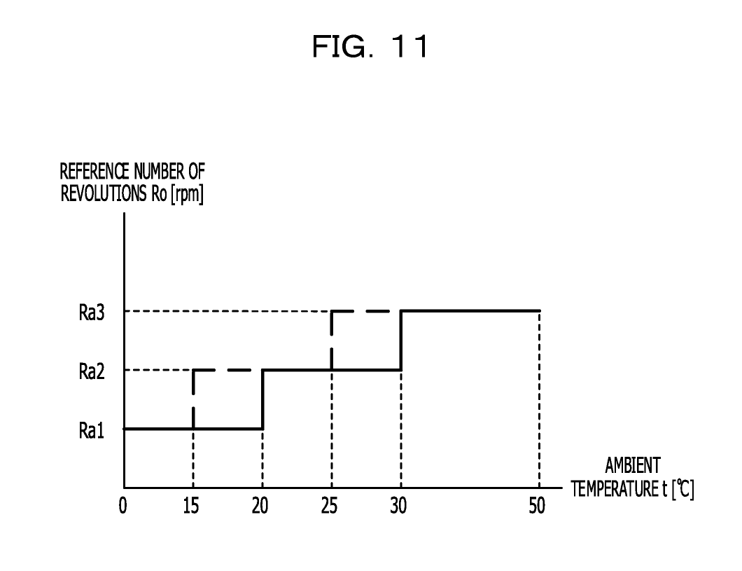

The aspect of changes in the reference number of revolutions Ro corresponding to the atmospheric pressure p is not limited to the example illustrated in FIG. 9. FIG. 11 is a graph illustrating another example of changes in atmospheric pressure versus changes in the reference number of revolutions Ro. In FIG. 11, a solid line represents the reference number of revolutions Ro at the atmospheric pressure (904 to 1013 hPa) of lowland (at an altitude of 0 to 1000 m). A dotted line represents the reference number of revolutions Ro at the atmospheric pressure (804 to 904 hPa) of a highland (at an altitude of 1000 to 2000 m).

In an example of FIG. 11, with changes in the atmospheric pressure, the range of the ambient temperature t corresponding to the reference number of revolutions Ra2 is changed from 20 to 30° C. to 15 to 25° C. And the range of the ambient temperature t corresponding to the reference number of revolutions Ra3 is changed from 30 to 50° C. to 25 to 50° C. In other words, the reference number of revolutions Ro corresponding to the range of the ambient temperature t of 15 to 20° C. is increased from Ra1 to Ra2, and the reference number of revolutions Ro of the range of the ambient temperature t of 25 to 30° C. is increased from the Ra2 to Ra3.

As seen above, also in this example, the clogging detection unit 100 may use the reference number of revolutions Ro corresponding to the atmospheric pressure p as a threshold and thus accurately detect clogging of the air filter 6. As in the example of FIG. 10, a table corresponding to this example would a table indicating the correspondence between the atmospheric pressure p and the reference number of revolutions Ro for each of the ranges of the ambient temperature t of 0 to 15° C., 15 to 20° C., 20 to 25° C., 25 to 30° C., and 30 to 50° C.

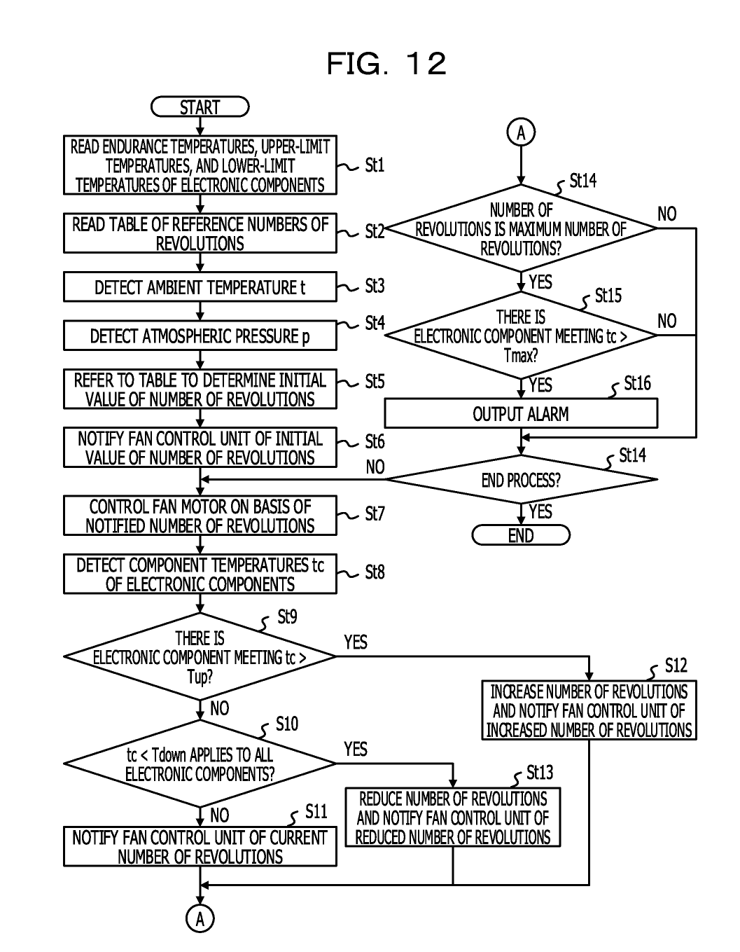

Next, a process of controlling the number of revolutions R of the cooling fan 30 will be described. FIG. 12 is a flowchart illustrating the process of controlling the number of revolutions R. In FIG. 12, circled symbols “A” are connected together. The flow of FIG. 12 is illustrated assuming that the fan units 3₁ to 3₃ mainly cool the single communication processing unit, 2₁.

First, the revolution control unit 101 reads the endurance temperatures Tmax1 to Tmax3, the upper-limit temperatures Tup1 to Tup3, and the lower-limit temperatures Tdown1 to Tdown3 of the electronic components A, B, and C 20₁ to 20₃ (step St1). At this time, the revolution control unit 101 reads these temperature parameters from the second memory 22.

The revolution control unit 101 then reads the table of the reference numbers of revolutions Ro from the third memory 31 (step St2). The revolution control unit 101 then detects the ambient temperature t using the first temperature sensor 12 (step St3). At this time, the first temperature sensor 12 detects the ambient temperature t and notifies the revolution control unit 101 of the detected ambient temperature.

The revolution control unit 101 then detects the atmospheric pressure p using the atmospheric pressure sensor 13 (step St4). At this time, the atmospheric pressure sensor 13 detects the atmospheric pressure p and notifies the revolution control unit 101 of the detected atmospheric pressure.

The revolution control unit 101 then refers to the table of the reference numbers of revolutions Ro and determines the initial value of the number of revolutions R (step St5). At this time, the revolution control unit 101 uses the reference number of revolutions Ro corresponding to the atmospheric pressure p detected by the atmospheric pressure sensor 13 and the ambient temperature t detected by the first temperature sensor 12, as the initial value of the number of revolutions R. Accordingly, the initial value of the number of revolutions R serves as an optimum value corresponding to the ambient temperature t and the atmospheric pressure p, and the amount of control that has to be performed to stabilize the number of revolutions R is reduced. As a result, power consumption is reduced.

The revolution control unit 101 then notifies the fan control unit 300 of the initial value of the number of revolutions R (step St6). Based on the number of revolutions R notified of by the revolution control unit 101, the fan control unit 300 controls the fan motor 301 (step St7). For example, as shown in FIG. 3, the fan motor 301 is controlled in steps in accordance with a PWM signal.

Subsequently, the revolution control unit 101 detects the component temperatures tc of the electronic components A, B, and C 20₁ to 20₃ (step St8). At this time, the second temperature sensors 21₁ to 21₃ detect the component temperatures tc of the electronic components A, B, and C 20₁ to 20₃, respectively, and notify the revolution control unit 101 of the detected component temperatures.

The revolution control unit 101 then determines whether there is an electronic component meeting “tc>Tup” among the electronic components A, B, and C 20₁ to 20₃ (step St9). If there is an electronic component meeting “tc>Tup” (Yes in step St9), the revolution control unit 101 increases the number of revolutions R and notifies the fan control unit 300 of the increased number of revolutions R (step St12). The width of increase may be a single step or multiple steps.

If there is no electronic component meeting “tc>Tup” (No in step St9), the revolution control unit 101 determines whether “tc<Tdown” applies to all the electronic components A, B, and C 20₁ to 20₃ (step St10). If “tc<Tdown” applies to all the electronic components (Yes in step St10), the revolution control unit 101 reduces the number of revolutions R and notifies the fan control unit 300 of the reduced number of revolutions R (step St13). The width of reduction may be a single step or multiple steps.

If “tc<Tdown” does not apply to all the electronic components (No in step St10), the revolution control unit 101 notifies the fan control unit 300 of the current number of revolutions R (step St11). At this time, the fan motor 301 maintains the current number of revolutions R. As seen above, the revolution control unit 101 controls the number of revolutions R with increase thereof given first priority. Thus, the component temperatures tc of all the electronic components A, B, and C 20₁ to 20₃ fall within the respective temperature ranges in which the performance of the electronic components is guaranteed.

The revolution control unit 101 then determines whether the number of revolutions R is the maximum number of revolutions (step St14). In the example of FIG. 3, the number of revolutions corresponding to step (16) is the maximum number of revolutions.

If the number of revolutions R is the maximum number of revolutions (Yes in step St14), the revolution control unit 101 determines whether there is an electronic component meeting “tc>Tmax” among the electronic components A, B, and C 20₁ to 20₃ (step St15). If there is an electronic component meeting “tc>Tmax” (Yes in step St15), the revolution control unit 101 outputs an alarm indicating a unit failure to the operation system 9 through the network NW (step St16).

If the revolution control unit 101 continues the control process (No in step St17), it performs step St7 again. If the determination in step St14 or step St15 is No (No in step St14 or step St15) and if the revolution control unit 101 continues the control process (No in step St17), the revolution control unit 101 performs step St7 again as well. In this way, the number of revolutions R of the cooling fan 30 is controlled.

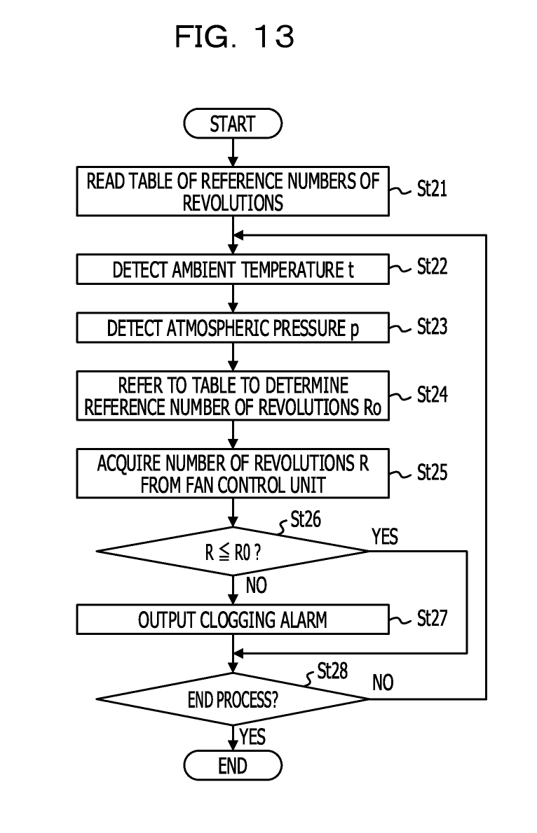

Next, a process of detecting clogging of the air filter 6 will be described. FIG. 13 is a flowchart illustrating the process of detecting clogging of the air filter 6.

First, the clogging detection unit 100 reads the table of the reference numbers of revolutions Ro from the third memory 31 (step St21). The clogging detection unit 100 then detects the ambient temperature t using the first temperature sensor 12 (step St22). At this time, the first temperature sensor 12 detects the ambient temperature t and notifies the clogging detection unit 100 of the detected ambient temperature.

The clogging detection unit 100 detects the atmospheric pressure p using the atmospheric pressure sensor 13 (step St23). At this time, the atmospheric pressure sensor 13 detects the atmospheric pressure p and notifies the clogging detection unit 100 of the detected atmospheric pressure.

Subsequently, the clogging detection unit 100 refers to the table of the reference numbers of revolutions Ro to determine the reference number of revolutions Ro (step St24). At this time, the clog detection unit 100 selects, from the table of the reference numbers of revolutions Ro, the reference number of revolutions Ro corresponding to the atmospheric pressure p detected by the atmospheric pressure sensor 13 and the ambient temperature t detected by the first temperature sensor 12.

The clogging detection unit 100 then acquires the number of revolutions R from the fan control unit 300 (step St25). The clogging detection unit 100 then determines whether R≦Ro (step St26).

If not R≦Ro (No in step St26), the clogging detection unit 100 outputs a clogging alarm to the operation system 9 (step St27). Specifically, when the number of revolutions R controlled by the revolution control unit 101 is greater than the reference number of revolutions Ro corresponding to the atmospheric pressure p detected by the atmospheric pressure sensor 13 and the ambient temperature t detected by the first temperature sensor 12, the clogging detection unit 100 determines that clogging has occurred in the air filter 6 and detects the clogging. As seen above, the clogging detection unit 100 may detect the clogging accurately using the threshold corresponding to the atmospheric pressure p and the ambient temperature t.

If the clogging detection unit 100 continues the detection process (No in step St28), it performs step St22 again. If R≦Ro (Yes in step St26) and if the clogging detection unit 100 continues the detection process (No in step St28), the clogging detection unit 100 performs step St22 again as well. In this way, the clogging of the air filter 6 is detected.

As described above, the cooling system according to the present embodiment includes the cooling fan 30, the first temperature sensor 12, the one or more second temperature sensors 21₁ to 21₃, the atmospheric pressure sensor 13, the revolution control unit 101, the third memory 31, and the clogging detection unit 100. The cooling fan 30 takes in air through the air filter 6 and sends the air to the one or more electronic components A, B, and C 20₁ to 20₃.

The one or more second temperature sensors 21₁ to 21₃ detect the component temperatures tc of the one or more electronic components A, B, and C 20₁ to 20₃. The atmospheric pressure sensor 13 detects the atmospheric pressure p, and the first temperature sensor 12 detects the ambient temperature t. Based on the component temperatures tc detected by the second temperature sensors 21₁ to 21₃, the revolution control unit 101 controls the number of revolutions R of the cooling fan 30.

The third memory 31 is storing the table indicating the correspondence between the atmospheric pressure p and the reference number of revolutions Ro for each of the ranges of the ambient temperature t. That is, the table illustrates the relationship among the ambient temperature, the atmospheric pressure, and the reference number of revolutions. The clogging detection unit 100 refers to the table and, when the number of revolutions R controlled by the revolution control unit 101 is greater than the reference number of revolutions Ro corresponding to the atmospheric pressure p detected by the atmospheric pressure sensor 13 and the ambient temperature t detected by the first temperature sensor 12, determines that clogging has occurred in the air filter 6 and detects the clogging.

According to the cooling system according to the present embodiment, the revolution control unit 101 controls the number of revolutions R of the cooling fan 30 on the basis of the component temperatures tc. Accordingly, when the component temperatures tc rise, it increases the number of revolutions R to reduce the component temperatures tc. For example, when the air filter 6 absorbs dust or the like due to intake of air and thus becomes clogged, the component temperatures tc rise. Accordingly, the revolution control unit 101 increases the number of revolutions R.

Since the effect of air blast depends on air density, the cooling capacity of the cooling fan 30 varies according to the installation environment (altitude). Accordingly, the number of revolutions R when the air filter 6 becomes clogged also varies according to the installation environment (altitude).

Since the clogging detection unit 100 refers to the table indicating the correspondence between the atmospheric pressure p and the reference number of revolutions Ro for each of the ranges of the ambient temperature t, it may select the reference number of revolutions Ro corresponding to the atmospheric pressure p detected by the atmospheric pressure sensor 13 and the ambient temperature t detected by the first temperature sensor 12. When the number of revolutions R controlled by the revolution control unit 101 is greater than the reference number of revolutions Ro corresponding to the detected atmospheric pressure p and the ambient temperature t detected by the first temperature sensor 12, the clogging detection unit 100 detects clogging of the air filter 6. As seen above, the clogging detection unit 100 may detect the clogging more accurately by using the appropriate reference number of revolutions Ro corresponding to the atmospheric pressure p and the ambient temperature t.

A method for detecting clogging of an air filter according to the present embodiment includes the following steps (1) to (3):
(1) detecting the component temperatures tc of the one or more electronic components A, B, and C 20₁ to 20₃, the ambient temperature t, and the ambient temperature p;
(2) controlling, based on the detected component temperatures tc, the number of revolutions R of the cooling fan 30, which takes in air through the air filter 6 and sends the air to the one or more electronic components A, B, and C 20₁ to 20₃; and
(3) referring to the table indicating the relationship among the ambient temperature t, the atmospheric pressure p, and the reference number of revolutions Ro and, when the number of revolutions R is greater than the reference number of revolutions Ro corresponding to the detected ambient temperature t and atmospheric pressure p, determining that clogging has occurred in the air filter 6 and detecting the clogging.

According to the method for detecting clogging of an air filter according to the present embodiment, effects similar to those described above are obtained.

In the above embodiment, the table of the reference numbers of revolutions Ro is a table indicating the reference number of revolutions Ro for each of the ranges of the ambient temperature t, but not limited thereto. For example, if the transmission apparatus is disposed in a place where the temperature changes to a lesser extent, the table of the reference numbers of revolutions Ro may be a table indicating the reference number of revolutions Ro corresponding to a given range of the ambient temperature t. This is because the ambient temperature t also changes to a lesser extent in such a place.

While, in the above embodiment, the clogging detection unit 100 and the revolution control unit 101 are disposed in the control unit 1, they may be disposed in the communication processing units 2₁ to 2₁₁ or fan units 3₁ to 3₃.

While, in the above embodiment, the air filter 6 is disposed in such a manner that it is commonly used by the multiple fan units 3₁ to 3₃, air filters 6 may be disposed in such a manner that they correspond to the individual fan units 3₁ to 3₃. In this case, the clogging detection unit 100 may perform a clogging detection process separately on each air filter 6 or may perform such a process collectively on all the air filters 6.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A cooling system comprising:
a cooling fan configured to take in air through an air filter and to send the air to one or more electronic components;
one or more first temperature detectors configured to detect temperatures of the one or more electronic components;
a revolution controller configured to control a number of revolutions of the cooling fan on basis of the temperatures detected by the one or more first temperature detectors; and
a clogging detector configured to, when the number of revolutions of the cooling fan controlled by the revolution controller is greater than a reference number of revolutions of the cooling fan that makes the temperature of the one or more electronic components less than upper-limit temperatures of the one or more electronic components, detect a clogging condition for the air filter.

2. The cooling system according to claim 1, further comprising:
an atmospheric pressure detector configured to detect atmospheric pressure; and
wherein the clogging detector, when the number of revolutions controlled by the revolution controller is greater than the reference number of revolutions corresponding to the reference temperature for the one or more electronic components and corresponding to an atmospheric pressure detected by the atmospheric pressure detector, detects the clogging condition for the air filter.

3. The cooling system according to claim 2, further comprising:
a second temperature detector configured to detect an external ambient temperature, wherein
the clogging detector detects the clogging condition for the air filter, when the number of revolutions controlled by the revolution controller is greater than the reference number of revolutions corresponding to the atmospheric pressure detected by the atmospheric pressure detector and the ambient temperature detected by the second temperature detector.

4. The cooling system according to claim 1, wherein
the revolution controller, when a temperature detected by the one or more first temperature detectors is higher than a first temperature threshold corresponding to the one or more electronic components, increases the number of revolutions.

5. The cooling system according to claim 4, wherein
the revolution controller, when temperature detected by all of the first temperature detectors are lower than a second temperature threshold corresponding to the one or more electronic components, reduces the number of revolutions.

6. The cooling system according to claim 2, wherein
the revolution controller uses the reference number of revolutions corresponding to the atmospheric pressure detected by the atmospheric pressure detector as an initial value of the number of revolutions.

7. The cooling system according to claim 2, wherein
the cooling fan is disposed in a communication processor.

8. The cooling system according to claim 4, wherein
the one or more electronic components are disposed in a communication processor.

9. A method for detecting clogging of an air filter, comprising:
detecting temperatures of one or more electronic components, an ambient temperature, and atmospheric pressure;
controlling the number of revolutions of a cooling fan on the basis of the detected temperatures, the cooling fan being configured to take in air through the air filter and to send the air to the one or more electronic components;
referring to a relationship among an ambient temperature, atmospheric pressure, and a reference number of revolutions of the cooling fan that makes the temperature of the one or more electronic components less than upper-limit temperatures of the one or more electronic components; and,
detecting a clogging condition for the air filter when the number of revolutions is greater than the reference number of revolutions corresponding to the detected ambient temperature and the detected atmospheric pressure.

10. The method for detecting clogging of an air filter according to claim 9, wherein
when a temperature of at least one of the one or more electronic components is higher than a first threshold corresponding to the electronic component, the number of revolutions is increased.

11. The method for detecting clogging of an air filter according to claim 9, wherein
when the temperatures of all of the electronic components are lower than second thresholds, respectively, corresponding to the electronic components, the number of revolutions is reduced.

12. The method for detecting clogging of an air filter according to claim 9, further comprising;
determining the reference number of revolutions corresponding to the detected ambient temperature and the detected atmospheric pressure is used as an initial value of the number of revolutions.

13. An signal transmission apparatus, comprising:
one or more circuit boards for processing signals;
a fan that blasts air towards the one or more circuit boards;
an air filter through which the fan draws in the air; and
computing hardware that determines a clogging condition of the air filter responsive to a detected number of revolutions of the fan exceeding a threshold number of revolutions of the fan exerting a cooling capacity corresponding to a threshold temperature for the one or more circuit boards.

14. The apparatus according to claim 13, wherein
the threshold number of revolutions of the fan is selectable according to an atmospheric pressure on basis of air density for an installation environment of the signal transmission apparatus.
